(19) United States
(12) Patent Application Publication
(10) Pub. No.: US 2016/0277028 A1
(43) Pub. Date: Sep. 22, 2016

(54) SEMICONDUCTOR DEVICE

(71) Applicant: PS4 LUXCO S.A.R.L., Luxembourg (LU)

(72) Inventor: Yasuhiro Takai, Tokyo (JP)

(21) Appl. No.: 14/777,966

(22) PCT Filed: Mar. 14, 2014
(86) PCT No.: PCT/JP2014/056849

§ 371 Date: Sep. 17, 2015

(30) Foreign Application Priority Data
Mar. 21, 2013 (JP) 2013-057775

(51) Int. Cl. H03K 19/0185; G11C 11/4091

(52) U.S. Cl. CPC H03K 19/018528; G11C 11/4091

(57) ABSTRACT

[Problem] To provide an input receiver making it possible to obtain adequate gain with respect to a broad reference potential level. [Solution] The present invention is provided with a differential circuit (110) and a current-supplying circuit (120). The differential circuit (110) includes a first input terminal to which a reference potential VREF is fed, and a second input terminal to which an input signal DQ is fed, the differential circuit (110) generating an output signal based on the difference in potential between the reference potential VREF and the input signal DQ. The current-supplying circuit (120) feeds an actuating current to the differential circuit (110). The actuating current includes the sum of first and second actuating currents. The current-supplying circuit (120) includes a common-mode feedback circuit (CMFB) and an assist circuit (TA). The common-mode feedback circuit (CMFB) changes the first actuating current in accordance with the level of the reference potential VREF. The assist circuit (TA) feeds a fixed amount of the second actuating current irrespective of the level of the reference potential VREF. It is thereby possible to obtain adequate gain with respect to a broad reference potential VREF level.

### TECHNICAL FIELD

The present invention relates to a semiconductor device, and in particular relates to a semiconductor device provided with an input receiver having a variable input signal reference level.

### BACKGROUND ART

Semiconductor devices such as DRAMs (Dynamic Random Access Memory) are provided with an input receiver which receives an input signal from the outside. A differential amplifier circuit which compares the level of the input signal with a reference potential and generates an output signal on the basis of the potential difference is generally used as the input receiver.

However, the level of the reference potential is not necessarily fixed, and the level of the reference potential may be switched depending on the specification or the operating environment. A technique known as common mode feedback is known as a method for correctly receiving the input signal even in such cases (see patent literature article 1).

Meanwhile, if the frequency of the input signal is high, the output signal output from the input receiver must also be transmitted rapidly. A function known as a de-emphasis function which reduces the amplitude is known as a method of transmitting a signal more rapidly (see patent literature article 2).

### PATENT LITERATURE

Patent literature article 1: Japanese Patent Kokai 2011-217252

Patent literature article 2: Japanese Patent Kokai 2007-60073

### SUMMARY

A common mode feedback circuit described in patent literature article 1 achieves the desired operation, even if the level of the reference potential varies, by employing a change-over switch to vary the bias level of a current mirror circuit. However, with such a circuit configuration it is difficult to accommodate wide-ranging multi-stage variations in the reference potential.

The semiconductor device according to the present invention is characterized in that it is provided with: a differential circuit comprising a first input terminal to which a reference potential is supplied, and a second input terminal to which an input signal is supplied, and which generates an output signal on the basis of a potential difference between the reference potential and the input signal; and a current supply circuit which supplies an operating current to the differential circuit; and in that the operating current comprises the sum of first and second operating currents; and the current supply circuit comprises a common mode feedback circuit which varies the first operating current in accordance with the level of the reference potential, and an assist circuit which supplies a fixed amount of the second operating current irrespective of the level of reference potential.

According to the present invention, the operating current of the differential circuit is varied in accordance with the level of the reference potential, and therefore wide-ranging multi-stage variations in the reference potential can be accommodated. Moreover, because an assist circuit which supplies a fixed operating current, irrespective of the level of the reference potential, is provided, the operating-current supply capability does not deteriorate when the reference potential is high.

### BRIEF DESCRIPTION OF THE DRAWINGS

FIG. 1 is a block diagram illustrating the overall structure of a semiconductor device 10 according to a preferred mode of embodiment of the present invention.

FIG. 2 is a drawing used to describe the connection relationship between the semiconductor device (DRAM) 10 according to this mode of embodiment and a controller 70 which controls the same, where (a) illustrates a state in which one semiconductor device 10 is connected to the controller 70 and (b) illustrates a state in which four semiconductor devices 10 are connected to the controller 70.

FIG. 3 is a circuit diagram of an input receiver 100.

FIG. 4 is an operational waveform diagram used to describe the function of a de-emphasis circuit 130.

FIG. 5 is a graph illustrating the relationship between the level of a reference potential VREF and the data transfer rate.

FIG. 6 is a characteristic diagram used to describe differences between the characteristics with and without the de-emphasis circuit 130.

### DETAILED DESCRIPTION

A preferred mode of embodiment of the present invention will now be described in detail with reference to the accompanying drawings.

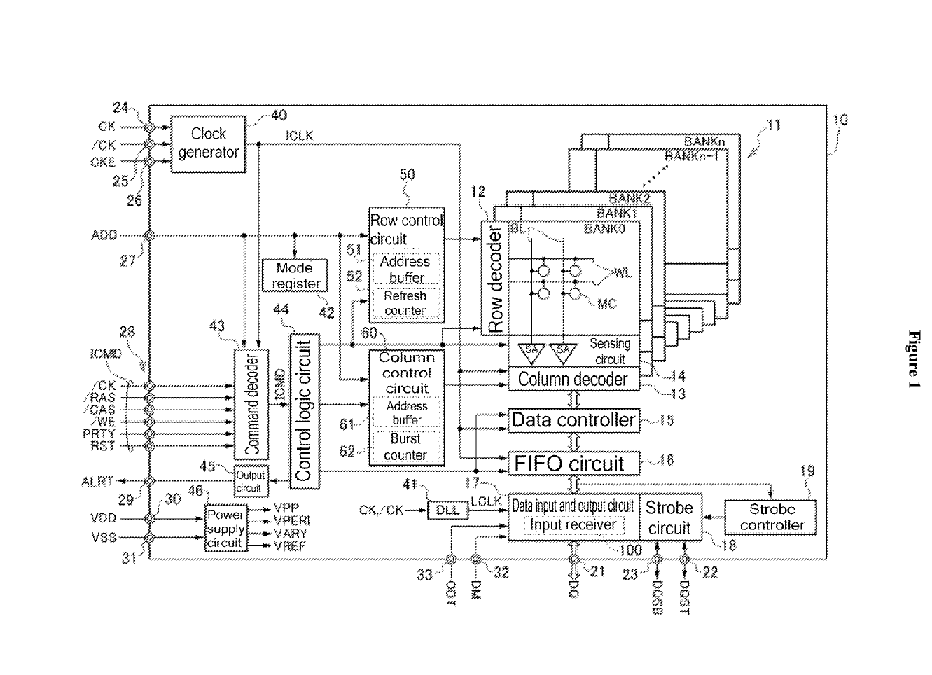

FIG. 1 is a block diagram illustrating the overall structure of a semiconductor device 10 according to a preferred mode of embodiment of the present invention.

The semiconductor device 10 according to this mode of embodiment is a DRAM integrated into one semiconductor chip, and as illustrated in FIG. 1, the semiconductor chip 10 is provided with a memory cell array 11 divided into n+1 banks. A bank is a unit capable of executing commands individually, and non-exclusive operation is essentially possible between the banks.

The memory cell array 11 is provided with a plurality of word lines WL and a plurality of bit lines BL which intersect one another, and memory cells MC are disposed at the points of intersection thereof. The word lines WL are selected using a row decoder 12, and the bit lines BL are selected using a column decoder 13. The bit lines BL are connected respectively to corresponding sense amplifiers SA in a sensing circuit 14, and the bit lines BL selected by the column decoder 13 are connected to a data controller 15 by way of the sense amplifiers SA. The data controller 15 is connected to a data input and output circuit 17 by way of a FIFO circuit 16. The data input and output circuit 17 is a circuit block which performs input and output of data by way of a data terminal 21, and contains an input receiver 100 discussed hereinafter.

Besides the data terminal 21, the semiconductor device 10 is provided, as external terminals, with strobe terminals 22 and 23, clock terminals 24 and 25, a clock enable terminal 26, an address terminal 27, command terminals 28, an alert terminal 29, power supply terminals 30 and 31, a data mask terminal 32 and an ODT terminal 33, for example.

The strobe terminals 22 and 23 are terminals for inputting and outputting external strobe signals DQST and DQSB respectively. The external strobe signals DQST and DQSB are complementary signals which determine the input and output timings of data input and output by way of the data terminal 21. More specifically, during data input, in other words during write operations, the external strobe signals DQST and DQSB are supplied to a strobe circuit 18, and the strobe circuit 18 controls the operational timing of the data input and output circuit 17 on the basis of the external strobe signals DQST and DQSB. By this means, write data DQ input by way of the data terminal 21 are taken in by the data input and output circuit 17 in synchronism with the external strobe signals DQST and DQSB. Meanwhile, during data output, in other words during read operations, the operation of the strobe circuit 18 is controlled by a strobe controller 19. By this means, read data DQ are output from the data input and output circuit 17 in synchronism with the external strobe signals DQST and DQSB.

The clock terminals 24 and 25 are terminals into which external clock signals CK and /CK are respectively input. The input external clock signals CK and /CK are supplied to a clock generator 40. In this specification, where a signal has a signal name beginning with 7′, this signifies a low-active signal or the inverted signal of a corresponding signal. Therefore the external clock signals CK and /CK are mutually complementary signals. The clock generator 40 is activated on the basis of a clock enable signal CKE input by way of a clock enable terminal 26, and the clock generator 40 generates an internal clock signal ICLK. Further, the external clock signals CK and /CK supplied by way of the clock terminals 24 and 25 are also supplied to a DLL circuit 41. The DLL circuit 41 is a circuit which generates an output clock signal LCLK, the phase of which is controlled on the basis of the external clock signals CK and /CK. The output clock signal LCLK is used as a timing signal which defines the output timing of the read data DQ from the data input and output circuit 17.

The address terminal 27 is a terminal to which an address signal ADD is supplied, and the supplied address signal ADD is supplied to a row control circuit 50, a column control circuit 60, a mode register 42 and a command decoder 43, for example. The row control circuit 50 is a circuit block which comprises an address buffer 51, a refresh counter 52 and the like, and which controls the row decoder 12 on the basis of a row address. Further, the column control circuit 60 is a circuit block which comprises an address buffer 61, a burst counter 62 and the like, and which controls the column decoder 13 on the basis of a column address. Further, if an entry is being made to a mode register setting, the address signal ADD is supplied to the mode register 42, and in response, the contents of the mode register 42 are updated.

The command terminals 28 are terminals to which a chip select signal /CS, a row address strobe signal /RAS, a column address strobe signal /CAS, a write enable signal /WE, a parity signal PRTY, a reset signal RST and the like are supplied. These command signals CMD are supplied to the command decoder 43, and the command decoder 43 generates internal commands ICMD on the basis of the command signals CMD. The internal command signals ICMD are supplied to a control logic circuit 44. The control logic circuit 44 controls the operations of the row control circuit 50 and the column control circuit 60, for example, on the basis of the internal command signals ICMD.

The command decoder 43 includes a verification circuit, which is not shown in the drawings. The verification circuit verifies the address signal ADD and the command signal CMD on the basis of the parity signal PRTY, and if the result is that there is an error in the address signal ADD or the command signal CMD, an alert signal ALRT is output by way of the control logic circuit 44 and an output circuit 45. The alert signal ALRT is output to the outside by way of the alert terminal 29.

The power supply terminals 30 and 31 are terminals supplied with power supply potentials VDD and VSS respectively. The power supply potentials VDD and VSS supplied by way of the power supply terminals 30 and 31 are supplied to a power supply circuit 46. The power supply circuit 46 is a circuit block which generates various internal potentials on the basis of the power supply potentials VDD and VSS. The internal potentials generated by the power supply circuit 46 include, for example, a boosted potential VPP, a power supply potential VPERI, an array potential VARY and the reference potential VREF. The boosted potential VPP is generated by boosting the power supply potential VDD, and the power supply potential VPERI, the array potential VARY and the reference potential VREF are generated by stepping down the external potential VDD.

The boosted voltage VPP is a potential used mainly in the row decoder 12. The word line WL selected on the basis of the address signal ADD is driven to the VPP level by the row decoder 12, and by this means the cell transistor included in the memory cell MC is caused to conduct. The internal potential VARY is a potential used mainly in the sensing circuit 14. When the sensing circuit 14 is activated, one of a pair of bit lines is driven to the VARY level, and the other of said pair of bit lines is driven to the VSS level, thereby amplifying read data that have been read. The power supply voltage VPERI is used as an operating potential for most of the peripheral circuits such as the row control circuit 50 and the column control circuit 60. By using the power supply potential VPERI, which is a lower voltage than the power supply potential VDD, as the operating potential for these peripheral circuits, a reduction in the power consumption of the semiconductor device 10 can be achieved. Further, the reference potential VREF is a potential used in the data input and output circuit 17. The level of the reference potential VREF can be switched according to the setting value in the mode register 42. The reason why it is necessary to switch the level of the reference potential VREF is discussed hereinafter.

The data mask terminal 32 and the ODT terminal 33 are terminals to which a data mask terminal DM and a termination signal ODT are respectively supplied. The data mask signal DM and the termination signal ODT are supplied to the data input and output circuit 17. The data mask signal DM is a signal activated if a portion of the write data and the read data is to be masked, and the termination signal ODT is a signal activated if an output buffer included in the data input and output circuit 17 is to be used as a termination resistor.

The overall structure of the semiconductor device 10 according to this mode of embodiment is as described above. The reason why it is necessary to switch the level of the reference potential VREF will now be explained.

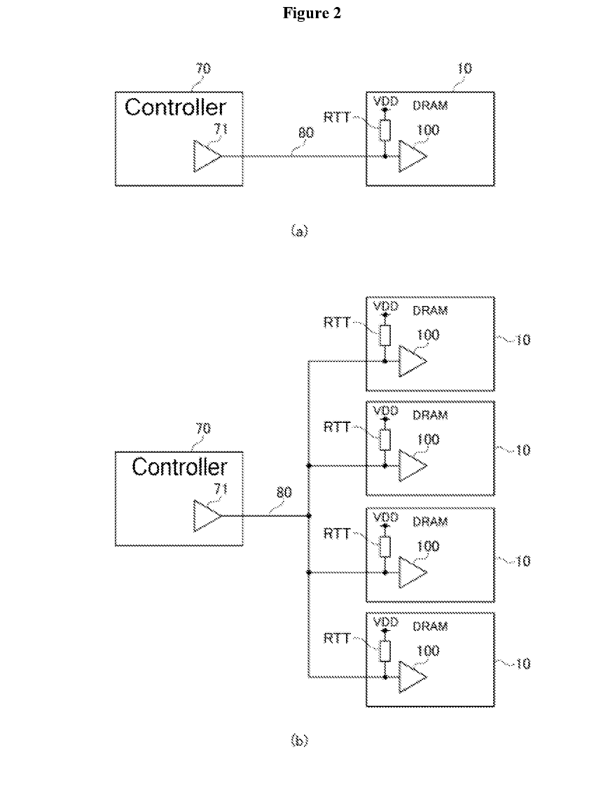

FIG. 2 is a drawing used to describe the connection relationship between the semiconductor device (DRAM) 10 according to this mode of embodiment and a controller 70 which controls the same, where (a) illustrates a state in which one semiconductor device 10 is connected to the controller 70 and (b) illustrates a state in which four semiconductor devices 10 are connected to the controller 70. FIG. 2 illustrates the connection relationship between an output buffer 71 contained in the controller 70 and the input receiver 100 contained in the semiconductor device 10.

Although there is no particular restriction, the semiconductor device 10 according to this mode of embodiment is a DDR4 (Double Data Rate 4) SDRAM (Synchronous DRAM), and the termination level of the data terminal 21 is set to the power supply potential VDD. Then, if the level of the data DQ is higher than the reference potential VREF, the logical value is determined to equal one, and if the level of the data DQ is lower than the reference potential VREF the logical value is determined to equal zero. With a DDR3 (Double Data Rate 3) or earlier SDRAM, the termination level of the data terminal 21 is an intermediate potential, namely VDD/2, and therefore the reference potential VREF should also be set to the intermediate potential VDD/2.

However, with a DDR4 SDRAM, the termination level of the data terminal 21 is the power supply potential VDD, and therefore the reference potential VREF differs depending on the number of semiconductor devices 10 connected to the controller 70. For example, supposing that the reference potential VREF is VDD×α if one semiconductor device 10 is connected to the controller 70, as illustrated in FIG. 2 (a), then if four semiconductor devices 10 are connected to the controller 70, as illustrated in FIG. 2 (b), it becomes necessary to change the reference potential VREF to VDD×β (β>α). This is because the number of termination resistors RTT connected to a data wiring line 80 differs between FIGS. 2 (a) and (b). With an actual DDR4 SDRAM, the level of the reference potential VREF is in a range of VDD×0.65 to 0.85.

For such reasons, if a DDR4 SDRAM is used as the semiconductor device 10, it is necessary to change the level of the reference potential VREF depending on the system configuration. Thus the input receiver 100 provided in the semiconductor device 10 must have circuit characteristics corresponding to a wide range of reference potential VREF levels. The input receiver 100 is a circuit included in the data input and output circuit 17 illustrated in FIG. 1, and the specific circuit configuration thereof will now be described in detail.

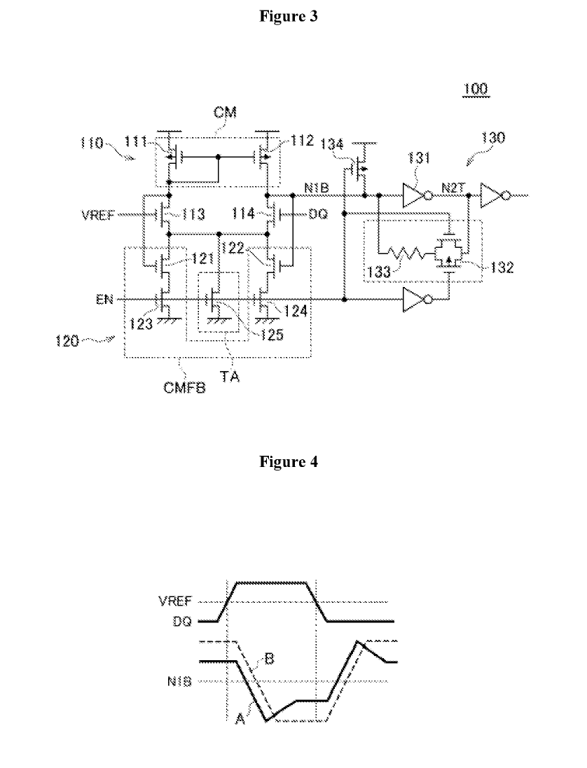

FIG. 3 is a circuit diagram of the input receiver 100.

As illustrated in FIG. 3, the input receiver 100 in this mode of embodiment is provided with a current-mirror type differential circuit 110, a current supply circuit 120 which supplies an operating current to the differential circuit 110, and a de-emphasis circuit 130 which reduces the amplitude of the output signal from the differential circuit 110.

The differential circuit 110 is provided with a current mirror circuit portion CM comprising P-channel MOS transistors 111 and 112. The sources of the transistors 111 and 112 are connected to a power source wiring line to which the power supply potential VDD is supplied, and the gate electrodes of the transistors 111 and 112 are connected in common to the drain of the transistor 111. By adopting this configuration, the drain of the transistor 111 forms an input terminal of the current mirror circuit portion CM, and the drain of the transistor 112 forms an output terminal of the current mirror circuit portion CM.

The drain of an input transistor 113 comprising an N-channel MOS transistor is connected to the input terminal of the current mirror circuit portion CM, and the drain of an input transistor 114 comprising an N-channel MOS transistor is connected to the output terminal of the current mirror circuit portion CM. The reference potential VREF is supplied to the gate electrode of the input transistor 113, and the write data DQ are supplied by way of the data terminal 21 to the gate electrode of the input transistor 114.

The differential circuit 110 with this configuration is operated by means of the operating current generated by the current supply circuit 120. The current supply circuit 120 includes a common mode feedback circuit CMFB which generates a first operating current, and an assist circuit TA which generates a second operating current. As illustrated in FIG. 3, the common mode feedback circuit CMFB and the assist circuit TA are connected in parallel, and therefore the operating current generated by the current supply circuit 120 is the sum of the first and second operating currents.

The common mode feedback circuit CMFB is provided with a control transistor 121 and a current supply transistor 123 connected in series between the sources of the input transistors 113 and 114 and a power source wiring line to which the ground potential VSS is supplied, and a control transistor 122 and a current supply transistor 124 which are similarly connected in series therebetween. Each of the transistors 121 to 124 is an N-channel MOS transistor. The gate electrode of the control transistor 121 is connected to the drain of the input transistor 113, in other words to the input terminal of the current mirror circuit portion CM, and the gate electrode of the control transistor 122 is connected to the drain of the input transistor 114, in other words to the output terminal of the current mirror circuit portion CM. Further, an enable signal EN is supplied to the gate electrodes of the current supply transistors 123 and 124.

The assist circuit TA comprises a current supply transistor 125 connected in series between the sources of the input transistors 113 and 114 and a power source wiring line to which the ground potential VSS is supplied. The transistor 125 is an N-channel MOS transistor, and the enable signal EN is supplied to the gate electrode thereof.

By means of this circuit configuration, when the enable signal EN is activated to the high level, the current supply transistors 123 to 125 are turned on, and the operating current is supplied to the differential circuit 110. From among the operating currents supplied to the differential circuit 110, the second operating current supplied by the assist circuit TA is effectively a fixed current. In contrast, the first operating current supplied by the common mode feedback circuit CMFB varies depending on the level of the reference potential VREF. More specifically, the first operating current decreases as the level of the reference potential VREF increases, and the first operating current increases as the level of the reference potential VREF decreases. In this way, a sufficient gain can be obtained over a wide range of reference potential VREF levels.

In this way, an output signal is output from the differential circuit 110 on the basis of the potential difference between the reference potential VREF and the write data (input signal) DQ. The output signal from the differential circuit 110 is extracted from an output node N1B, which is the output terminal of the current mirror circuit portion CM. The output node N1B is connected to the de-emphasis circuit 130.

The de-emphasis circuit 130 is provided with an inverter 131 which receives the output signal from the differential circuit 110, and a transfer gate 132 and a resistive element 133 which are connected in series between the input and output nodes of the inverter 131. The transfer gate 132 turns on when the enable signal EN is activated to the high level. Thus, when the enable signal EN is activated to the high level, the input and output nodes of the inverter 131 are short-circuited by means of the resistive element 133. As a result, the amplitude of the output signal output from the output node N2T is reduced. Meanwhile, when the enable signal EN is inactivated to the low level, the transfer gate 132 turns off, and therefore the consumption current arising from the short-circuiting of the input and the output nodes of the inverter 131 is cut. Further, in this case a P-channel MOS transistor 134 is turned on, and the level of the output node N1B is thus fixed to the power supply potential VDD.

FIG. 4 is an operational waveform diagram used to describe the function of the de-emphasis circuit 130.

The waveform A illustrated in FIG. 4 represents the waveform at the output node N2T when the de-emphasis circuit 130 is provided, and the waveform B represents the waveform at the output node N2T when the de-emphasis circuit 130 is removed, in other words when the feedback group comprising the transfer gate 132 and the resistive element 133 is removed. As illustrated by the waveform A in FIG. 4, when the de-emphasis circuit 130 is provided the level of the output signal corresponding to the period in which the data DQ does not change is closer to the intermediate potential VDD/2. In essence, the potential level when the logic level is 1 (high level) decreases, and conversely the potential level when the logic level is 0 (low level) increases. As a result, the amplitude becomes smaller, and therefore when the data DQ has changed, the period until the output signal reaches the intermediate potential VDD/2, which is a crosspoint, is reduced, and thus rapid signal transmission is possible.

The configuration of the input receiver 100 according to this mode of embodiment is as described hereinabove. As discussed hereinabove, in the input receiver 100 in this mode of embodiment, the current supply circuit 120 which supplies the operating current to the differential circuit 110 is provided with the common mode feedback circuit CMFB. Thus desired characteristics can be obtained even if the level of the reference potential VREF is switched. However, if the operating current is supplied to the differential circuit 110 using only the common mode feedback circuit CMFB, the supply capability may deteriorate when the reference potential is high. Accordingly, although a problem arises in that circuit design becomes more difficult, it is possible to eliminate such problems in this mode of embodiment by providing the assist circuit TA in addition to the common mode feedback circuit CMFB. In this way, a sufficient gain can be obtained over a wide range of reference potential VREF levels.

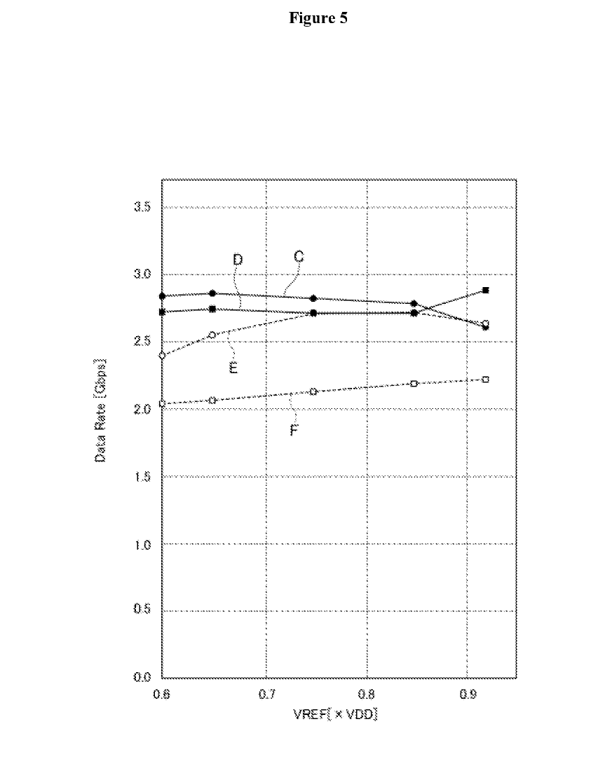

FIG. 5 is a graph illustrating the relationship between the level of the reference potential VREF and the data transfer rate.

In FIG. 5, characteristics C and D are characteristics when both the common mode feedback circuit CMFB and the assist circuit TA are used, and of these, the characteristic C illustrates the characteristic at a high temperature (110° C.), and the characteristic D illustrates the characteristic at a low temperature (−5° C.). Further, the characteristics E and F are characteristics when the assist circuit TA is removed, in other words characteristics when the operating current is supplied to the differential circuit 110 using only the common mode feedback circuit CMFB, and of these, the characteristic E illustrates the characteristic at a high temperature) (110°, and the characteristic F illustrates the characteristic at a low temperature (−5° C.). As illustrated by the characteristics C and D in FIG. 5, it can be seen that when both the common mode feedback circuit CMFB and the assist circuit TA are used, rapid operation occurs correctly over a wide range of reference potential VREF levels, irrespective of the operating temperature. In contrast, as illustrated by the characteristics E and F in FIG. 5, if the assist circuit TA is removed, there is a pronounced temperature dependence, and at low temperatures the data transfer rate is reduced. This is because at low temperatures the threshold of the N-channel MOS transistors increases, and the saturation characteristic current a (VGS-VTN)² decreases. However, if the assist circuit TA is added, a triode characteristic current is supplemented, and as a result it is possible to achieve a high data transfer rate even at low temperatures.

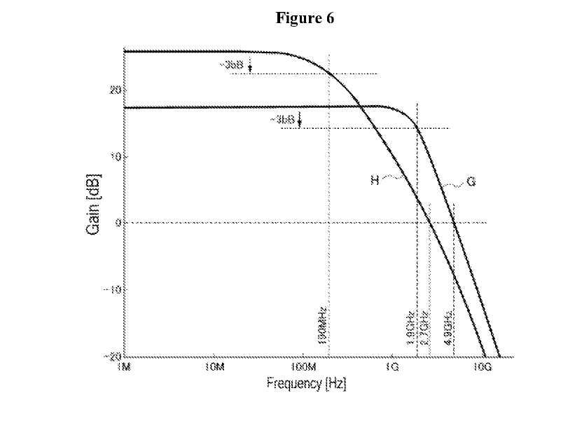

FIG. 6 is a characteristic diagram used to describe differences between the characteristics with and without the de-emphasis circuit 130.

The characteristic G illustrated in FIG. 6 represents the frequency characteristic of the input receiver 100 when the de-emphasis circuit 130 is provided, and the characteristic H represents the frequency characteristic of the input receiver 100 when the de-emphasis circuit 130 is removed, in other words when the feedback group comprising the transfer gate 132 and the resistive element 133 is removed. As illustrated in FIG. 6, it can be seen that in the low-frequency region a larger gain is obtained without the de-emphasis circuit 130, whereas in the high-frequency region, which is used in practice, the gain can be increased by providing the de-emphasis circuit 130. Further, the cutoff frequency at which the gain drops by 3 dB is 190 MHz in characteristic H, but is increased to 1.9 GHz in characteristic G. Moreover, the bandwidth to the point at which the gain reaches 0 dB is increased from 2.7 GHz to 4.9 GHz.

As described hereinabove, with the input receiver 100 in this mode of embodiment a sufficient gain can be obtained over a wide range of reference potential VREF levels, irrespective of the operating temperature.

Preferred modes of embodiment of the present invention have been described hereinabove, but various modifications to the present invention may be made without deviating from the gist of the present invention, without limitation to the abovementioned mode of embodiment, and it goes without saying that these are also included within the scope of the present invention.

For example, MOS transistors are used as the transistors in the input receiver 100 illustrated in FIG. 3, but other types of transistors, such as bipolar transistors, may also be used.

Further, in the de-emphasis circuit 130 illustrated in FIG. 3, the input and output nodes of the inverter 131 are short-circuited, but there is no particular restriction to the specific circuit configuration of the de-emphasis circuit, and any circuit configuration may be used provided that the in-phase component and the reverse-phase component of the output signal from the differential circuit are combined.

### EXPLANATION OF THE REFERENCE CODES

10 Semiconductor device
11 Memory cell array
12 Row decoder
13 Column decoder
14 Sensing circuit
15 Data controller
16 FIFO circuit
17 Data input and output circuit
18 Strobe circuit
19 Strobe controller
21 Data terminal
22, 23 Strobe terminal
24, 25 Clock terminal
26 Clock enable terminal
27 Address terminal
28 Command terminals
29 Alert terminal
30, 31 Power supply terminal
32 Data mask terminal
33 ODT terminal
40 Clock generator
41 DLL circuit
42 Mode register
43 Command decoder
44 Control logic circuit
45 Output circuit
46 Power supply circuit
50 Row control circuit
51 Address buffer
52 Refresh counter
60 Column control circuit
61 Address buffer
62 Burst counter
70 Controller
71 Output buffer
80 Data wiring line
100 Input receiver
110 Differential circuit
111, 112 Transistor
113, 114 Input transistor
120 Current supply circuit
121, 122 Control transistor
123-125 Current supply transistor
130 De-emphasis circuit
131 Inverter
132 Transfer gate
133 Resistive element
134 Transistor
CM Current mirror circuit portion
CMFB Common mode feedback circuit
RTT Termination resistor
TA Assist circuit

1. A semiconductor device comprising:
a differential circuit comprising a first input terminal to which a reference potential is supplied, and a second input terminal to which an input signal is supplied, and which generates an output signal on the basis of a potential difference between the reference potential and the input signal; and
a current supply circuit which supplies an operating current to the differential circuit wherein the operating current comprises the sum of first and second operating currents;
wherein the current supply circuit comprises a common mode feedback circuit which varies the first operating current in accordance with the level of the reference potential, and an assist circuit which supplies the second operating current as a current of fixed value, irrespective of the level of reference potential.

2. The semiconductor device as claimed in claim 1, wherein:
the differential circuit comprises a current mirror circuit portion, a first input transistor, one end of which is connected to an input terminal of the current mirror circuit portion, and a second input transistor, one end of which is connected to an output terminal of the current mirror circuit portion;
the reference potential is supplied to a control electrode of the first input transistor;
the input signal is supplied to a control electrode of the second input transistor; and
the output signal is output from an output terminal of the current mirror circuit portion.

3. The semiconductor device as claimed in claim 2, wherein:
the common mode feedback circuit comprises a first control transistor and a first current supply transistor connected in series between the other ends of the first and second input transistors and a power source wiring line, and a second control transistor and a second current supply transistor connected in series between said other ends of the first and second input transistors and the power source wiring line;
the control electrode of the first control transistor is connected to the input terminal of the current mirror circuit portion; and
the control electrode of the second control transistor is connected to the output terminal of the current mirror circuit portion.

4. The semiconductor device as claimed in claim 3, wherein the assist circuit comprises a third current supply transistor connected between said other ends of the first and second input transistors and the power source wiring line.

5. The semiconductor device as claimed in claim 4, wherein an enable signal is supplied in common to the control electrodes of the first to third current supply transistors.

6. The semiconductor device as claimed in claim 1, further comprising a mode register which holds a setting value relating to the level of the reference potential.

7. The semiconductor device as claimed in claim 1, further comprising a de-emphasis circuit which reduces the amplitude of the output signal.

8. The semiconductor device as claimed in claim 7, wherein the de-emphasis circuit reduces the amplitude of the output signal by combining the in-phase component and the reverse-phase component of the output signal.

9. The semiconductor device as claimed in claim 8, wherein the de-emphasis circuit comprises an inverting circuit which inverts the logic level of the output signal, and a short circuit which short-circuits the input terminal and the output terminal of the inverting circuit.

10. The semiconductor device as claimed in claim 9, wherein the short circuit comprises a resistive element connected between the input terminal and the output terminal of the inverting circuit.

11. The semiconductor device as claimed in claim 10, wherein the short circuit additionally comprises a switch circuit which disconnects the input terminal and the output terminal of the inverting circuit from one another.

12. A semiconductor device comprising:
a current mirror circuit connected between a first and a second node;
a first transistor which is connected between the first node and a third node, and to a control terminal of which a reference potential is supplied;
a second transistor which is connected between the second node and a fourth node, and to a control terminal of which an input signal is supplied;
a third transistor which is connected to the third node, and to a control terminal of which the first node is connected;
a fourth transistor which is connected to the fourth node, and to a control terminal of which the second node is connected; and
a fifth transistor which is connected to the third and fourth nodes, and to a control terminal of which a certain fixed potential is supplied when the current mirror circuit is activated.
